(19) United States
(12) Patent Application Publication
(10) Pub. No.: US 2026/0302306 A1
(43) Pub. Date: Oct. 1, 2026

(54) STACKED ELECTROCHEMICAL CELL SYSTEMS

(71) Applicant: Bloom Energy Corporation, San Jose, CA (US)

(72) Inventors: Ryan JOHNSON, San Jose, CA (US); Rueben M. KEMPTON, San Jose, CA (US); Samuel JUDAY, Tahoe City, CA (US); Prabu SOMASUNDARAM, Cupertino, CA (US); Jessica MAHLER, Palo Alto, CA (US); Nilanjana BASU, Santa Clara, CA (US)

(21) Appl. No.: 19/578,077

(22) Filed: Mar. 25, 2026

Related U.S. Application Data
(60) Provisional application No. 63/777,899, filed on Mar. 26, 2025.

(51) Int. Cl. H01M 8/249; H01M 8/2404; H01M 8/2484; H05K 5/02; H05K 7/18

(52) U.S. Cl. CPC H01M 8/249; H01M 8/2404; H01M 8/2484; H05K 5/0213; H05K 7/183

(57) ABSTRACT

A generator stack includes a lower skid, a row of lower power modules disposed on the lower skid, support columns extending vertically from the lower skid, an upper skid disposed on the support columns over the row of lower power modules, and a row of upper power modules disposed on the upper skid. The lower power modules and the upper power modules each include a hotbox and at least one stack of electrochemical cells disposed in the hotbox.

### FIELD

The present disclosure is directed generally to multilevel electrochemical cell systems, such as fuel cell or electrolyzer cell systems.

### BACKGROUND

Rapid and inexpensive installation can help to increase the prevalence of electrochemical systems, such as fuel cell systems and electrolyzer cell systems. Installation costs for pour-in-place custom designed concrete pads, which generally require trenching for plumbing and electrical lines, can be costly. Installation time is also a problem in the case of most sites since concrete pours and trenches generally require one or more building permits and building inspector reviews.

Furthermore, stationary fuel cell and/or electrolyzer cell systems may be installed in locations where the cost of real estate is quite high or the available space is limited (e.g., a loading dock, a narrow alley or space between buildings, etc.). When the number of fuel cell and/or electrolyzer cell systems to be installed on a site increases, one problem which generally arises is that stand-off space between these systems is required (to allow for maintenance of one unit or the other unit). The space between systems represents lost opportunity in terms of its potential to be used by the customer of the system. The system installation should have a high utilization of available space. When a considerable amount of stand-off space is required for access to the system via doors and the like, installation real estate costs increase significantly.

In the case of some fuel cell and/or electrolyzer cell system designs, these problems are resolved by increasing the overall capacity of the monolithic system design. However, this creates new challenges as the size and weight of the concrete pad required increases. Therefore, this strategy tends to increase the system installation time. Furthermore, as the minimum size of the system increases, the fault tolerance of the design is reduced.

### SUMMARY

According to various embodiments, a generator stack includes a lower skid, a row of lower power modules disposed on the lower skid, support columns extending vertically from the lower skid, an upper skid disposed on the support columns over the row of lower power modules, and a row of upper power modules disposed on the upper skid. The lower power modules and the upper power modules each include a hotbox and at least one stack of electrochemical cells disposed in the hotbox.

### BRIEF DESCRIPTION OF THE DRAWINGS

FIG. 1 is a perspective view of a fuel cell module set, according to various embodiments of the present disclosure.

FIG. 2A is a perspective view showing a generator stack, according to various embodiments of the present disclosure, FIG. 2B is a perspective view showing a support frame of FIG. 2A.

FIG. 3 is a perspective view of a support column of the support frame of FIG. 2B.

FIG. 4A is a side view of a generator stack, according to various embodiments of the present disclosure, FIG. 4B is an enlarged view showing portion P of FIG. 4A, and FIG. 4C is a perspective view showing an alternative version of the components of FIG. 4B.

FIG. 5A is a perspective view of a generator stack, according to various embodiments of the present disclosure, and FIG. 5B is a perspective view of a portion of a support frame of FIG. 5A.

FIG. 6A is a perspective view of a system, according to various embodiments of the present disclosure, and FIG. 6B is cross-sectional view of the system of FIG. 6A. FIG. 6C is a perspective cut-away view of an exhaust diverter of the system of FIGS. 6A and 6B.

FIG. 7A is a side view of another system, according to various embodiments of the present disclosure, FIG. 7B is a perspective view of the back side of one generator stack of the system of FIG. 7A, and FIG. 7C is a cross-sectional view of a duct joint of FIG. 7A.

FIG. 8A is a perspective view of another system, according to various embodiments of the present disclosure, and FIG. 8B is cross-sectional view of the system of FIG. 8A.

FIG. 9 is an external backside view of an exemplary power module according to various embodiments of the present disclosure.

FIG. 10A is a perspective view showing a portion of an exhaust manifold that may be disposed on an associated power module, according to various embodiments of the present disclosure, and FIG. 10B is a perspective view showing cabinet exhaust and electronics exhaust flow through a ventilation unit of FIG. 10A.

FIGS. 11A-11L illustrate steps in exemplary methods of assembling a system, according to various embodiments of the present disclosure. FIG. 11B shows the expanded view of region B in FIG. 11A. FIG. 11D shows the expanded view of region D in FIG. 11C. FIG. 11F shows the expanded view of region F in FIG. 11E. FIG. 11H shows the expanded view of region H in FIG. 11G. FIG. 11J shows the expanded view of region J in FIG. 11I. FIG. 11K shows the expanded view of region K in FIG. 11J. FIG. 11L shows the expanded view of region L in FIG. 11J.

FIGS. 12A-12D and 12G-12J are perspective views and FIGS. 12E and 12F are side views of system components during another method of assembling a system, according to another embodiment of the present disclosure.

FIGS. 13A and 13B are side views of adjacent systems of FIG. 12J illustrating the location of the utility connections according to various embodiments of the present disclosure.

### DETAILED DESCRIPTION

It is to be understood that both the foregoing general description and the following detailed description are exemplary and explanatory only and are not restrictive of the invention as claimed.

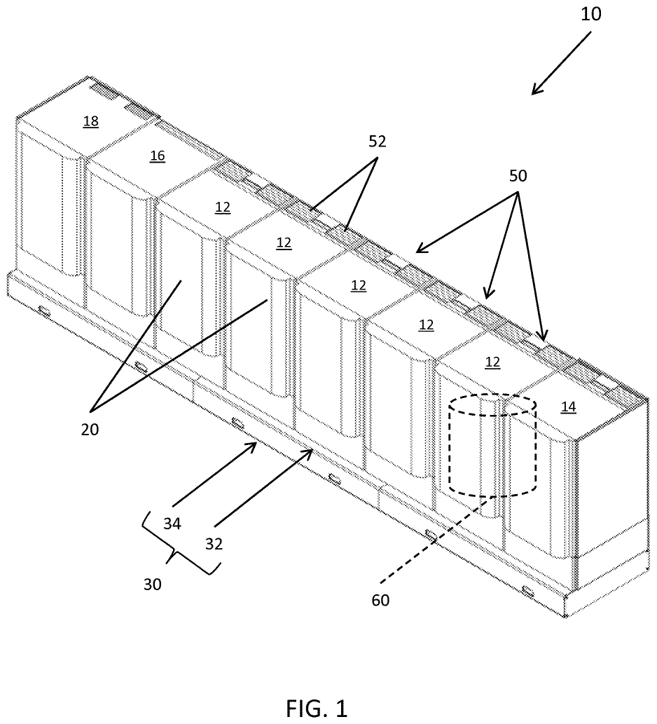

FIG. 1 is a perspective view of a fuel cell module set 10, according to various embodiments of the present disclosure. Referring to FIG. 1, the module set 10 may have a modular system layout. The module set 10 may contain modules and components described in U.S. Pat. Nos. 9,190,693, 9,755,263, 10,797,327 and 11,862,832, all of which are incorporated herein by reference in their entireties. A modular design of the module set 10 may provide flexible system installation and operation. Modules allow scaling of installed generating capacity, reliable generation of power, flexibility of fuel processing, and flexibility of power output voltages and frequencies with a single design set. The modular design results in an “always on” unit with very high availability and reliability. This design also provides an easy means of scale up and meets specific requirements of customer installations. The modular design also allows the use of available fuels and required voltages and frequencies which may vary by customer and/or by geographic region.

The module set 10 shown in FIG. 1 includes multiple power modules 12, an optional accessory module 14, a fuel processing module 16, and a power conditioning (i.e., electrical output) module 18. Each module 12, 14, 16, 18 may comprise a respective cabinet (e.g., a housing, such as a metal housing) having a respective door 20 to access the modules 12, 14, 16, 18. The fuel cell and/or electrolyzer cell stacks or columns of the power modules 12 may be located in hot boxes (i.e., thermally insulated containers) 60 located in the power module cabinets behind the doors 20.

The module set 10 of FIG. 1 may be disposed on a skid 30 that supports the modules 12, 14, 16, 18. The skid 30 may include an upper surface (i.e., a deck) 32 that rests upon rails 34 that are connected to the deck 32. The skid 30 may be configured to enable quick deployments and/or temporary deployments of the module set 10 and may reduce installation costs and cycle times.

While one row of five power modules 12 is shown in FIG. 1, the module set 10 may comprise any number of power modules 12 (e.g., 1 to 20, such as 4 to 12 power modules) and any number of rows of power modules 12, such as two or more rows (e.g., two to ten rows). Each power module 12 is configured to house at least one hotbox 60. Each hotbox 60 contains one or more stacks or columns of electrochemical cells (e.g., fuel cells, not shown for clarity), such as one or more stacks or columns of solid oxide fuel cells having a ceramic oxide electrolyte separated by conductive interconnect plates. Other fuel cell types, such as PEM, molten carbonate, phosphoric acid, etc. may also be used. Alternatively, the electrochemical cells may be electrolyzer cells in an embodiment where the module set 10 comprises a hydrogen generation system rather than a fuel cell power generator.

The fuel cell stacks may comprise externally and/or internally manifolded stacks. For example, the stacks may be internally manifolded for fuel and air with fuel and air risers extending through openings in the fuel cell layers and/or in the interconnect plates between the fuel cells as disclosed in U.S. patent application Ser. No. 18/945,911, filed on Nov. 13, 2024, entitled “Internally Manifolded Interconnects with Plural Flow Directions and Electrochemical Cell Column Including Same,” which is incorporated herein by reference in its entirety.

Alternatively, the fuel cell stacks may be internally manifolded for fuel and externally manifolded for air, where only the fuel inlet and exhaust risers extend through openings in the fuel cell layers and/or in the interconnect plates between the fuel cells, as described in U.S. Pat. No. 7,713,649, which is incorporated herein by reference in its entirety. The fuel cells may have a cross flow (where air and fuel flow roughly perpendicular to each other on opposite sides of the electrolyte in each fuel cell), counter flow parallel (where air and fuel flow roughly parallel to each other but in opposite directions on opposite sides of the electrolyte in each fuel cell) or co-flow parallel (where air and fuel flow roughly parallel to each other in the same direction on opposite sides of the electrolyte in each fuel cell) configuration.

Each power module 12 may include a ventilation unit 50 disposed on the back side of the power module 12 cabinet, opposite to the door 20. The ventilation units 50 may be configured to output module exhaust vertically through vents 52. The module exhaust may include stack exhaust generated by electrochemical cell stacks located in the hotboxes 60, and cabinet air exhausted from the module cabinet. The ventilation units 50 may include a fan (not shown) to facilitate the output of the cabinet air exhaust.

The fuel processing module 16 includes components for pre-processing of fuel, such as adsorption beds (e.g., desulfurizer and/or other impurity adsorption) beds. The fuel processing module 16 may be designed to process a particular type of fuel. For example, the system may include a diesel fuel processing module, a natural gas fuel processing module, and an ethanol fuel processing module, which may be provided in the same or in separate cabinets. A different bed composition tailored for a particular fuel may be provided in each module. The processing module(s) 16 may process at least one of the following fuels selected from natural gas provided from a pipeline, compressed natural gas, methane, propane, liquid petroleum gas, gasoline, diesel, home heating oil, kerosene, JP-5, JP-8, aviation fuel, hydrogen, ammonia, ethanol, methanol, syn-gas, bio-gas, bio-diesel and other suitable hydrocarbon or hydrogen containing fuels. If desired, the fuel processing module 16 may include a reformer. Alternatively, if it is desirable to thermally integrate the reformer with the fuel cell stack(s), then a separate reformer may be located in each hotbox 60 in a respective power module 12. Furthermore, if internally reforming fuel cells are used, then an external reformer may be omitted entirely.

The power conditioning module 18 includes components for converting the fuel cell stack generated DC power to AC power (e.g., DC/DC and DC/AC converters described in U.S. Pat. No. 7,705,490, incorporated herein by reference in its entirety), electrical connectors for AC power output to the grid, circuits for managing electrical transients, and a system controller (e.g., a computer or dedicated control logic device or circuit). The power conditioning module 18 may be designed to convert DC power from the fuel cell power modules to different AC voltages and frequencies. Designs for 208V, 60 Hz; 480V, 60 Hz; 415V, 50 Hz and other common voltages and frequencies may be provided.

The fuel processing module 16 and the power conditioning module 18 may be housed in one cabinet, in some embodiments. If a single input/output cabinet is provided, then modules 16 and 18 may be located vertically (e.g., power conditioning module 18 components above the fuel processing module 16 desulfurizer canisters/beds) or side by side in the cabinet.

The ancillary equipment module 14 may include one or more additional system components. For example, the ancillary equipment module 14 may include water treatment components (e.g., water deionizers) and water distribution pipes and valves which may be connected to a water supply (e.g., a municipal water supply pipe), and to the individual modules in the module set 10. The ancillary equipment module 14 may also include power storage components, such as batteries and/or ultracapacitors (also known as supercapacitors), which may support the generator in meeting step load changes. If a single cabinet is utilized for power conditioning components and fuel processing components (e.g., modules 18 and 16 are combined in one cabinet), the module set 10 as illustrated in FIG. 1 could have two ancillary equipment module cabinets. In that case, one ancillary equipment module could comprise batteries and/or ultracapacitors and the other ancillary equipment module could constitute a “plus one” location for eventual connection of another power module 12 when needed to increase the output of the module set 10.

In some embodiments, the ancillary equipment module 14 may include system controllers and communication equipment that enables the module set 10 to communicate with a central controller and/or system operators. In some embodiments, the ancillary equipment module 14 may also include a power distribution components (e.g., DC/DC converters, etc.) configured to control power distribution to various components located on and/or off of the skid 30. In some embodiments, the ancillary equipment module 14 may also include disconnect switchgear, which may be configured to protect, isolate and de-energize components of the module set 10 in the event of a fault condition and/or for maintenance purposes. In some embodiments, the disconnect switchgear may be combined with or substituted with a backup power supply (BPS). A disconnect/BPS system on-board the skid 30 may allow for quick and easier installation as a disconnect/BPS does not have to be set during construction. In some embodiments, ancillary equipment module 14 may include an electrical distribution system that is configured to provide power distribution, telemetry, and disconnect/BPS functions in a single unit.

The linear array of power modules 12 is readily scaled. For example, more or fewer power modules 12 may be provided depending on the power needs of the building or other facility serviced by the module set 10. The power modules 12 and input/output modules 16/18 may also be provided in other ratios. For example, in other exemplary embodiments, more or fewer power modules 12 may be provided. Further, the support functions could be served by more than one input/output module 16/18 (e.g., with a separate fuel processing module 16 and power conditioning module 18 cabinets). Additionally, while in the preferred embodiment, the input/output module 16/18 is at the end of the row of power modules 12, it could also be located in the center of a row power modules 12.

The module set 10 may be configured in a way to ease servicing of the components of the module set 10. All of the routinely or high serviced components (such as the consumable components) may be placed in a single module to reduce the amount of time required for the service person. For example, a purge gas (optional) and desulfurizer material for a natural gas fueled system may be placed in a single module (e.g., a fuel processing module 16 or a combined input/output module 16/18 cabinet). This would be the only module cabinet accessed during routine maintenance. Thus, each module 12, 16, and 18 may be serviced, repaired or removed from the system without opening the other module cabinets and without servicing, repairing or removing the other modules.

For example, as described above, the module set 10 can include multiple power modules 12. When at least one power module 12 is taken off line (i.e., no power is generated by the stacks in the hotbox 60 in the off line module 12), the remaining power modules 12, the fuel processing module 16 and the power conditioning module 18 (or the combined input/output module 16/18) are not taken off line. Furthermore, the module set 10 may contain more than one of each type of module 12, 16, or 18. When at least one module of a particular type is taken off line, the remaining modules of the same type are not taken off line.

Thus, in a system comprising a plurality of modules, each of the modules 12, 14, 16, or 18 may be electrically disconnected, removed from the module set 10 and/or serviced or repaired without stopping an operation of the other modules in the system, allowing the fuel cell system to continue to generate electricity. The entire module set 10 does not have to be shut down if one stack of fuel cells in one hotbox 60 malfunctions or is taken off line for servicing.

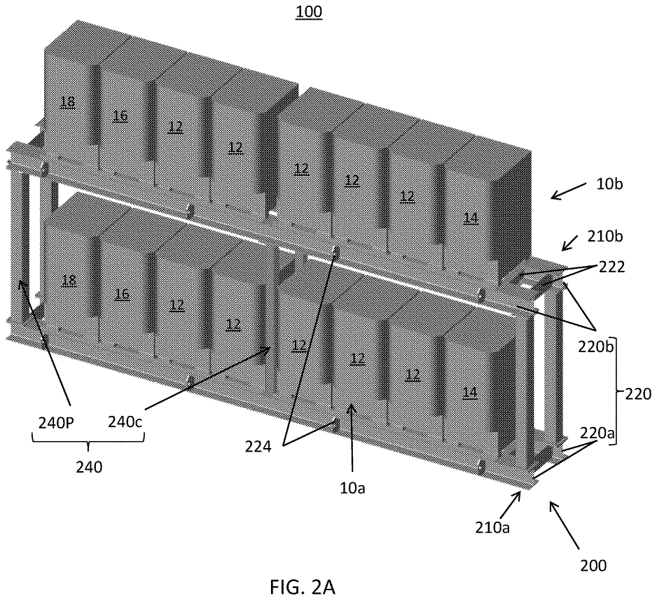

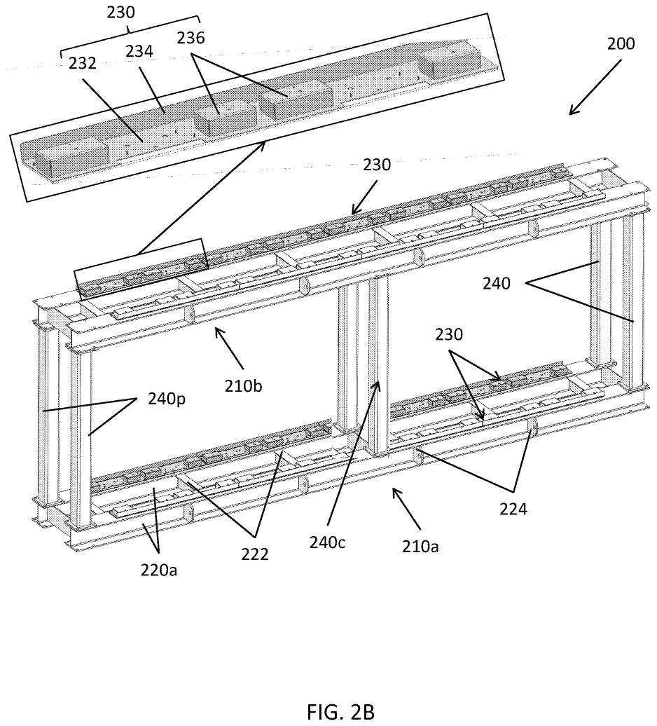

FIG. 2A is a perspective view showing a generator stack 100, according to various embodiments of the present disclosure, and FIG. 2B is a perspective view showing a support frame 200 of FIG. 2A. The generator stack 100 may comprise a fuel cell power generator stack or an electrolyzer cell hydrogen generator stack.

Referring to FIGS. 2A-2B, the generator stack 100 may include vertically stacked module sets 10 disposed on the support frame 200. In particular, the generator stack 100 may include a lower module set 10a and an upper module set 10b supported over the lower module set 10a by the support frame 200. The support frame 200 may be formed of a metal or metal alloy, such as steel or the like. The support frame 200 may include a lower skid 210a and an upper skid 210b that are connected to one another by columns 240, such as peripheral columns 240p and optional central columns 240c. The lower skid 210a may include lower skid beams 220a and the upper skid 210b may include upper skid beams 220b. Herein, the upper and lower skid beams 220a, 220b may be referred to collectively as skid beams 220. The skid beams 220 of each skid 210a, 210b may be connected by cross braces 222. The cross braces 222 may be welded to the skid beams 220 to provide additional lateral rigidity. The skid beams 220 and/or the cross braces 222 may be formed from a metal or metal alloy, such as steel or the like. In some embodiments, the skid beams 220 and/or the cross braces 222 and may be in the form of I-beams.

The support frame 200 may also include attachment plates 224. The attachment plates 224 may be welded to the skid beams 220. For example, the attachment plates 224 may be welded on three sides to the corresponding skid beams 220. In some embodiments, the attachment plates 224 may include through holes and may operate as attachment points for cables used for lifting the skids 210a, 210b using a crane or the like. The attachment plates 224 may also be configured to increase the strength and/or stiffness of the skid beams 220.

The support frame 200 may also include pedestal assemblies 230, as shown in FIG. 2B. The pedestal assemblies 230 may be attached to the skid beams 220. The pedestal assemblies 230 may each include a base 232, a wall 234 and pedestals 236. The base 232 may be bolted or welded to the upper surface of a corresponding skid beam 220. The wall 234 may extend vertically from the base 232. For example, the base 232 and the wall 234 may be formed by bending a metal sheet. In an alternative embodiment, the wall 234 may be welded to the base 232.

The pedestals 236 may be rectangular structures that are welded and/or bolted to the base 232. The pedestals 236 may be configured to support the modules of the module sets 10a, 10b. For example, the support frame 200 may include four pedestal assemblies 230 for each module of a supported module set. Thus, the pedestal assemblies 230 may function as the deck 32 of the respective skid 30, while the skid beams 220 function as the skid rails 34 of the respective skid 30 (e.g., 210a or 210b).

The peripheral columns 240p and the central columns 240c may be bolted or welded to the skid beams 220 to support the upper skid 210b above the lower skid 210a. In some embodiments, the central columns 240c may extend from the middle of the lower skid beams 220a to support the middle of the upper skid beams 220b. For example, the central columns 240c may extend between power modules 12 of the lower module set 10a, and the power modules 12 may be spaced apart to allow the central columns 240c to extend between the power modules 12.

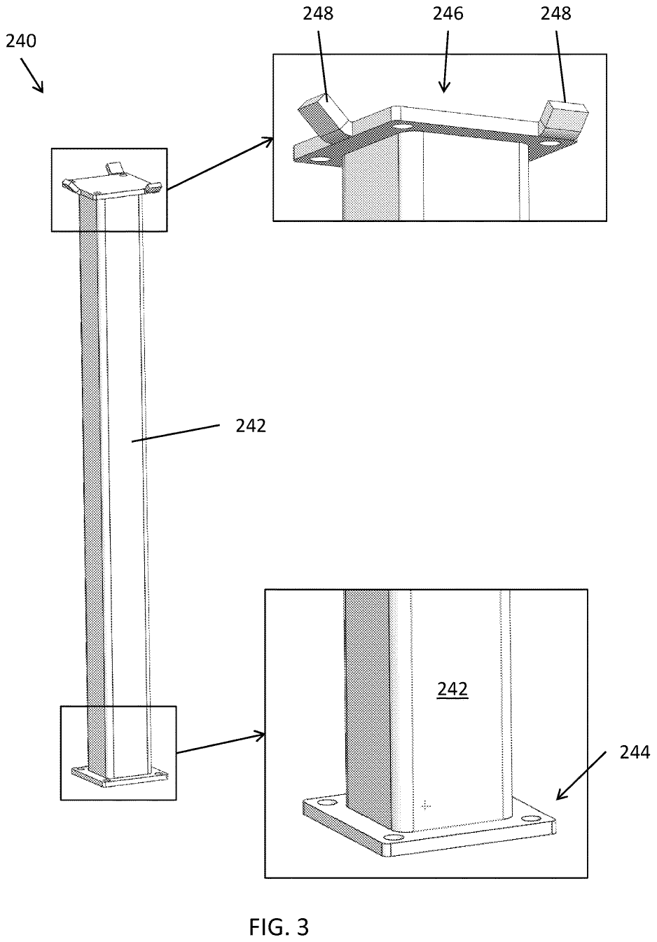

Referring to FIG. 3, the columns 240 may each include a body (e.g., pillar) 242, a lower bracket 244, and an upper bracket 246. The brackets 244, 246 may be welded to opposing ends of the body 242. The body 242 may have a rectangular or circular horizontal cross-section. The brackets 244, 246 may be bolted to the lower and upper skid beams 220a, 220b. In some embodiments, the upper brackets 246 may be configured to align the upper module set 10b with respect to the lower module set 10a when the upper module set 10b is placed on the upper skid 210b.

In one embodiment, the upper brackets 246 may include one or more alignment guides 248. For example, the upper brackets 246 of the peripheral columns 240p may include three alignment guides 248, as shown in FIG. 3. However, the present disclosure is not limited to any particular number of alignment guides 248. For example, in some embodiments the columns 240 may include one, two or more than three alignment guides 248. The alignment guides 248 may comprise protrusions which protrude in a diagonal direction between vertical and horizontal from the upper brackets 246.

The module sets 10a, 10b may be disposed on the respective skids 210a, 210b. In particular, the walls 234 may at least partially align the modules of the module sets 10a, 10b with the pedestals 236 and the modules may be bolted to the pedestals 236. The upper skid 210b and the upper module set 10b may be lifted onto the peripheral columns 240p and the central columns 240c and attached to the upper brackets 246. In particular, the upper brackets 246 may facilitate alignment of the upper skid 210b, such that bolt holes of the upper skid beams 220b and bolt holes of the upper brackets 246 are properly aligned and the upper skid beams 220b can be bolted to the upper brackets 246.

According to various embodiments, a module set 10 may have a mass of at least 12,000 kg. Since the lower skid 210a may be disposed on the ground, the lower skid 210a may be fully supported and generally has no issues supporting this mass. However, the present inventors determined that this mass may result in a significant amount of vertical displacement of the upper skid 210b and/or lateral displacement of the supported modules. In addition, end regions of the upper skid beams 220b that overlap with the peripheral columns 240p may be subjected to a significant amount of stress.

Referring again to FIGS. 2A-2B, the addition of the central columns 240c may reduce the maximum stress applied to the upper skid beams 220b by at least about 80%, such as from about 85% to about 95%, as compared to support frames that lack the central columns. For example, the central columns 240c may reduce the maximum stress applied to the upper skid beams 220b from greater than 260 MPa to less than 30 MPa.

In addition, the maximum vertical displacement of the upper skid beams 220b may be reduced by at least 90%, such as from about 90% to about 97%, as compared to support frames that lack central columns. Accordingly, the central columns 240c may reduce the maximum vertical displacement of the upper skid beams 220b to 2 mm or less. For example, the maximum vertical displacement may range from about 0.25 mm to about 2 mm, such as from about 1 mm to about 0.5 mm. In comparison, without the central columns 240c, the maximum vertical displacement may be greater than 10 mm.

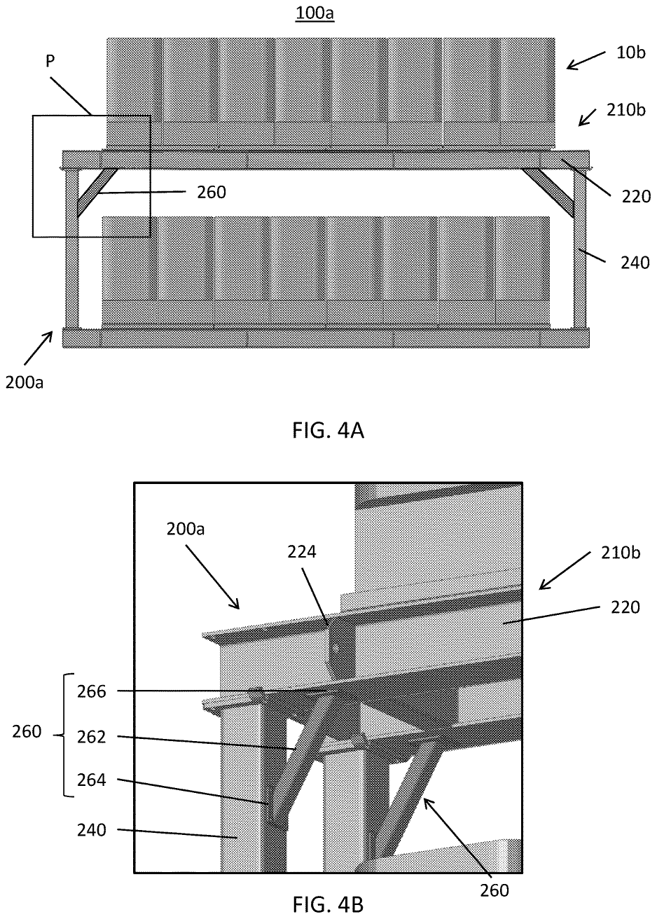

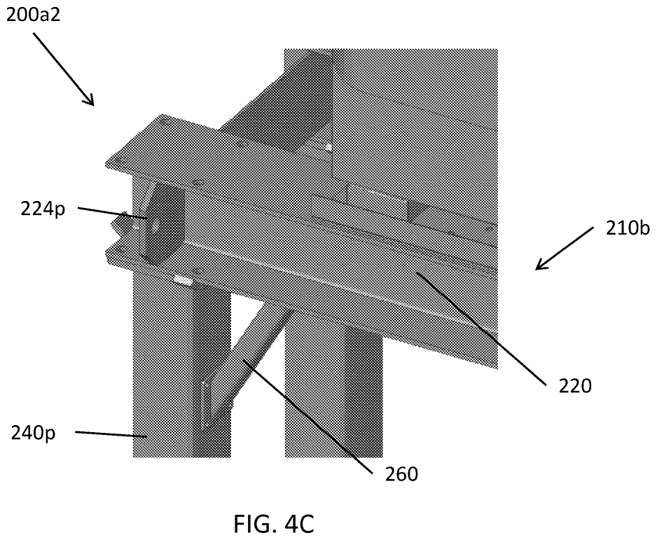

FIG. 4A is a side view of a generator stack 100a, according to various embodiments of the present disclosure, FIG. 4B is an enlarged view showing portion P of FIG. 4A, and FIG. 4C is a perspective view showing an alternative version of the components of FIG. 4B. The generator stack 100a may be similar to the generator stack 100 of FIG. 2A. As such, only the differences therebetween will be discussed in detail.

Referring to FIGS. 4A and 4B, the generator stack 100a may include a support frame 200a comprising corner braces 260 that connect the peripheral columns 240p to the upper skid beams 220b. The support frame 200a may optionally lack the central support beams 240c. The corner braces 260 may be welded or bolted to the peripheral columns and the upper skid beams 220b. In particular, the corner braces 260 may each include a main body 262, a lower bracket 264, and an upper bracket 266. The lower brackets 264 may be bolted to the peripheral columns 240p and the upper brackets 266 may be bolted to the upper skid beams 220b.

An angle formed between each corner brace 260 and the corresponding peripheral column 240p may range from about 20° to 40°, such as from about 25° to about 35°, or about 30°. An angle formed between each brace 260 and the corresponding upper skid beam 220b may range from about 50° to about 70°, such as from about 55° to about 65°, or about 60°.

The corner braces 260 may be configured to reduce the stress applied to the upper skid beams 220b by at least 25%, such as from about 25% to about 35%, as compared to support frames that lack braces. For example, the corner braces 260 may reduce the maximum stress applied to the upper skid beams 220b from greater than 260 MPa to less than 160 MPa.

In addition, the maximum vertical displacement of the upper skid beams 220b may be reduced by at least 25%, such as from about 25% to about 35%, as compared to support frames that lack the corner braces. Accordingly, the corner braces 260 may reduce the maximum vertical displacement of the upper skid beams 220b from greater than 10 mm to less than 8 mm.

Referring to FIG. 4C, the support frame 200a2 may include peripheral attachment plates 224p. The peripheral attachment plates 224p may be similar to the attachment plates 224 discussed above but may be disposed above the peripheral columns 240p at ends of the upper skid beams 220b. The peripheral attachment plates 224p may be included in addition to the attachment plates 224 shown in FIGS. 4A and 4B. In an alternative embodiment, the outermost attachment plates 224 may be moved closer to the ends of the upper skid beams 220b to form the peripheral attachment plates 224p.

The peripheral attachment plates 224p may reinforce the ends of the upper skid beams 220b where stress is concentrated. For example, the peripheral attachment plates 224p may vertically overlap with corresponding peripheral columns 240p. As such, the peripheral attachment plates 224p may additionally reduce the maximum stress applied to the upper skid beams 220b by at least 8%, such as from about 8% to about 15% as compared to the support frame 200a of FIG. 4B which lacks the peripheral attachment plates 224p. For example, the peripheral attachment plates 224p may reduce the maximum stress applied to the upper skid beams 220b by at least 20 MPa. In other words, the combination of the corner braces 260 and the peripheral attachment plates 224p may reduce the maximum amount of beam stress by at least 50%, as compared to a support frame that lacks peripheral attachment plates 224p and corner braces 260.

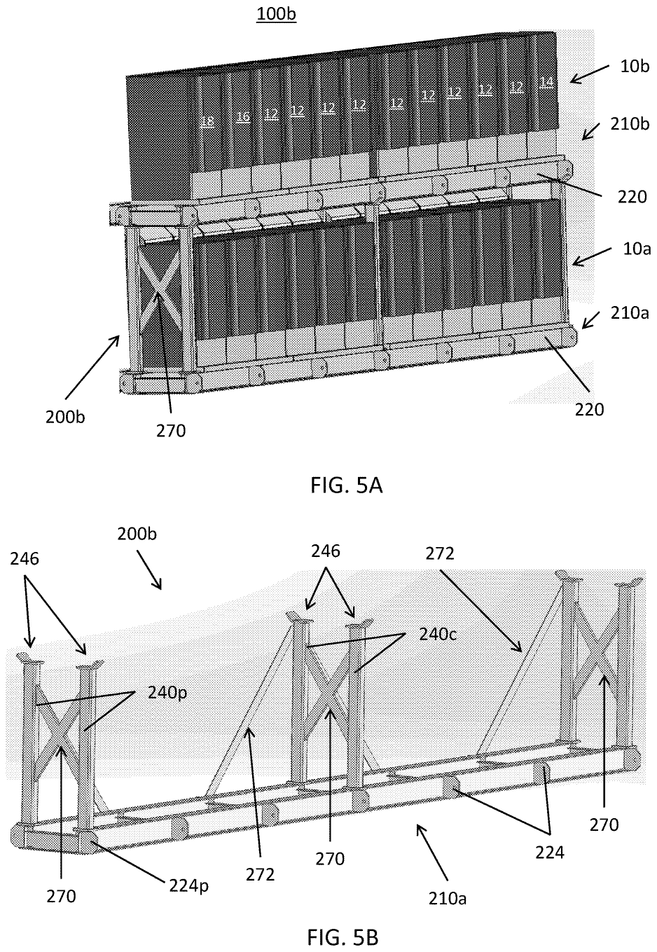

FIG. 5A is a perspective view of a generator stack 100b, according to various embodiments of the present disclosure, and FIG. 5B is a perspective view of a portion of a support frame 200b of FIG. 5A. The generator stack 100b may be similar to the generator stack 100a. As such, only the differences therebetween will be discussed in detail.

Referring to FIGS. 5A and 5B, the generator stack 100b may include a lower module set 10a and an upper module set 10b that are supported by a support frame 200b. The module sets 10a, 10b may include an increased number of modules 12, 14, 16, 18, as compared to the module sets described above. For example, the module sets 10a, 10b of FIG. 5A may each include twelve modules 12, 14, 16, 18.

As such, the support frame 200b may include additional structural elements to account for the additional weight of the module sets 10a, 10b. In particular, the support frame 200b may include latitudinal bracing (e.g., side cross braces) 270 and longitudinal bracing (e.g., back corner braces) 272. The latitudinal bracing 270 may be bolted or welded to the columns 240p, 240c to provide additional lateral support to the support frame 200a. The longitudinal bracing 272 may be bolted or welded to the columns 240p, 240c and the lower skid 210a to longitudinally strengthen the support frame 200b. The support frame 200b may also include additional attachment plates 224 to facilitate lifting of the module sets 10a, 10b.

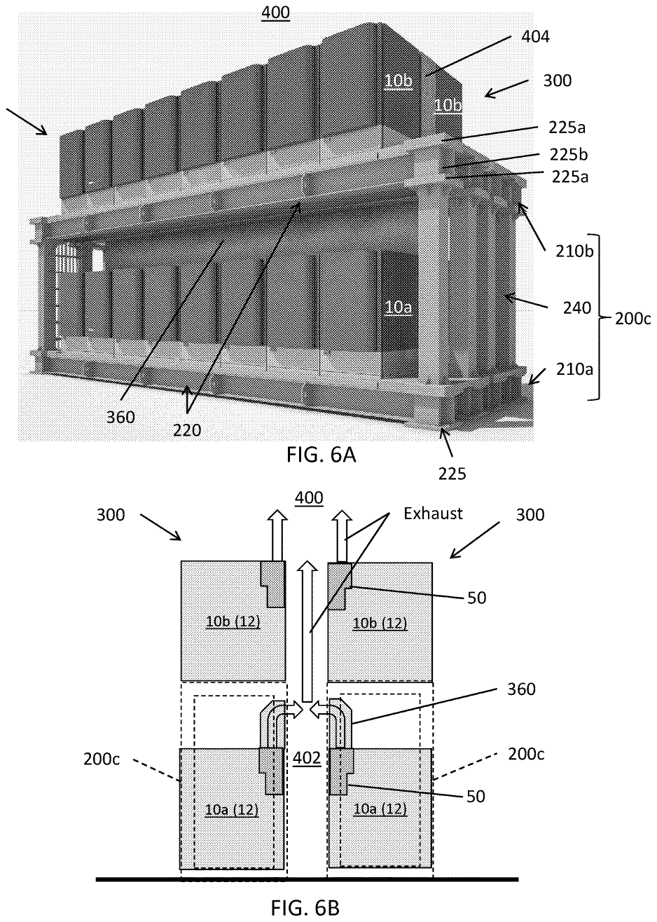

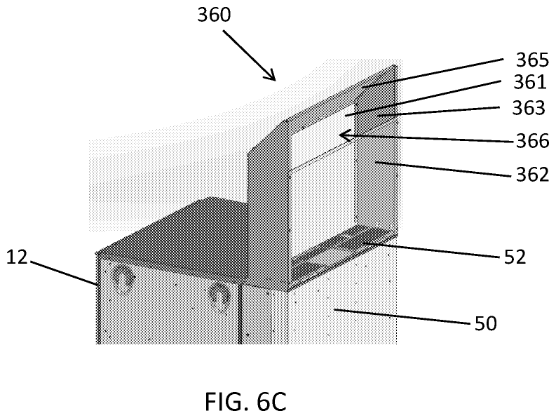

FIG. 6A is a perspective view of a system 400, according to various embodiments of the present disclosure, and FIG. 6B is cross-sectional view of the system 400 of FIG. 6A. The system 400 may include various components as described above. Accordingly, only the differences therebetween will be described in detail.

Referring to FIGS. 6A and 6B, the system 400 may include multiple power or hydrogen generator stacks 300, which may be the same as or similar to any of the generator stacks 100, 100a or 100b as described above. For example, the generator stacks 300 may each include a lower module set 10a, an upper module set 10b, and a support frame 200c. The support frame 200c may be any of the support frames 200, 200a, 200a2 or 200b described herein. In some embodiments, the support frame 200c may include a lower and upper skids 210a, 210b that are connected by columns 240. The lower and upper skids 210a, 210b may include corner supports 225 that are configured to strengthen portions of the skid beams 220 that are connected to the columns 240. The corner supports 225 may include horizontal plates 225a and vertical plates 225b that are attached (e.g., welded) to ends of the skid beams 220 to provide additional strength. The generator stacks 300 may be laterally separated from each other so as to form an aisle 402, and back sides of the modules of each module set 10a, 10b may face the aisle 402. Opposing ends of the aisle 402 may be covered by optional side panels 404.

The upper module sets 10b may emit exhaust in a vertical direction, directly from the ventilation units 50 of the power modules 12 (see FIG. 1) thereof. The lower module sets 10a may include exhaust diverters 360 located over the ventilation units 50 and configured to divert exhaust output from the power modules 12 into the aisle 402. In particular, the exhaust diverters 360 may be configured to prevent a high temperature hotbox 60 exhaust from being output from the power modules 12 of the lower module sets 10a directly towards the upper module set 10b. As such, the exhaust diverters 360 may protect the upper module set 10b from thermal damage. The exhaust output from the exhaust diverters 360 may flow up through the aisle 402 and out of the system 400.

Referring to FIG. 6C, in one embodiment, the exhaust diverter 360 may comprise a hollow prism-shaped body having a front wall 361, a back wall 362, sidewalls 363, a sloped roof 365 and an opening 366 located in the back wall 362. The exhaust diverter 360 may have an open bottom end located over the ventilation unit 50 of the power modules 12. The exhaust output from the power modules 12 flows upwards from the ventilation unit into the exhaust diverter 360, and then diagonally in the backward and upward direction through the opening 366 into the aisle 402. However, in alternative embodiments, the exhaust diverter 360 may have a different configuration.

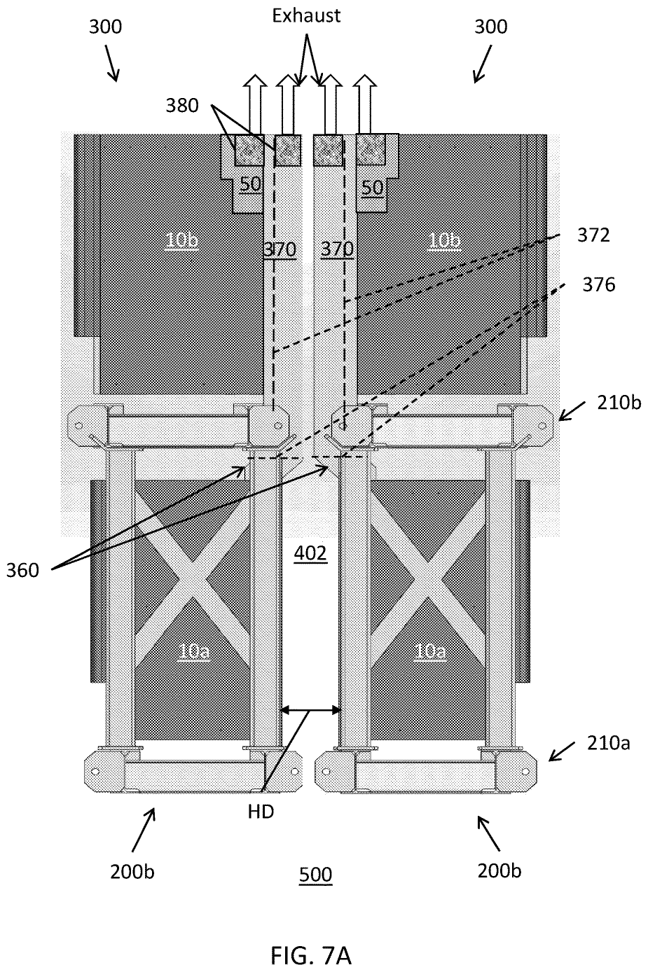

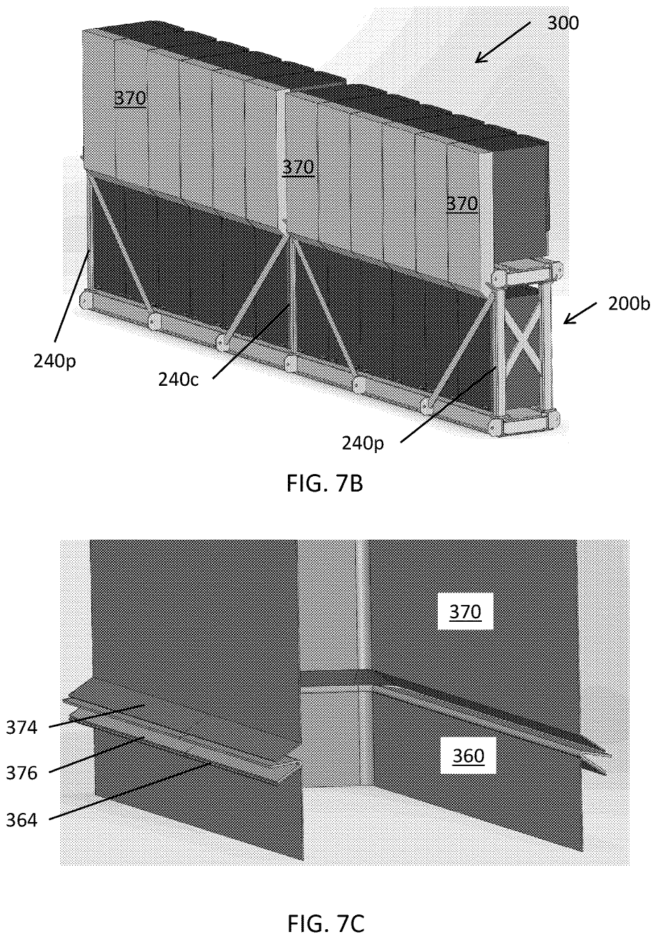

FIG. 7A is a side view of another system 500, according to various embodiments of the present disclosure, FIG. 7B is a perspective view of the back side of one generator stack 300 of the system 500 of FIG. 7A, and FIG. 7C is a cross-sectional view of a duct joint of FIG. 7A. The system 500 may be similar to the system 400. Accordingly, only the differences therebetween will be described in detail. Specifically, in the system 500, the exhaust from the lower module sets 10a is exhausted through vertical exhaust ducts 370, instead of being exhausted into the aisle 402 between the upper module sets 10b, as in system 400.

Referring to FIGS. 7A and 7B, the system 500 may include at least two generator stacks 300 disposed back to back. The system 500 may also include the exhaust ducts 370 that are fluidly connected to each of the exhaust diverters 360. The exhaust ducts 370 may vertically extend along the back sides of the upper module sets 10b and may be configured to transport exhaust to the top of the system 500.

In some embodiments, the exhaust ducts 370 may optionally include plenums 372 configured to divide the exhaust ducts into separate compartments. One of the compartments may be configured to receive relatively cool exhaust, such as cabinet air exhaust, and the other one of the compartments may be configured to receive relatively hot exhaust, such as reaction exhaust output from hotboxes 60 of the lower module sets 10a.

In an embodiment, the upper module set 10b and upper skid 210b may be laterally offset outward (i.e., outward relative to the aisle 402) from the lower module set 10a and lower skid 210a. This lateral offset may provide additional space for the exhaust ducts 370 in the aisle 402.

In one embodiment, the system 500 may include filter modules 380 disposed in the exhaust ducts 370 and/or the ventilation units 50 of the upper module sets 10b. The filter modules 380 may include electrostatic filters configured to remove particulates from the exhaust stream. The filter modules 380 to be accessed from above the system 500. As such, a horizontal distance HD between the generator stacks 300 (i.e., the width of the aisle 402) may be reduced, since access to the back side of the generator stacks 300 may not be necessary to service the filter modules 380, and additional area for the exhaust ducts 370 may be provided by the lateral offset of the upper and lower module sets 10a, 10b.

Referring to FIG. 7C, the diverter 360 and the exhaust duct 370 may be connected by a gasket 376. In this embodiment an outlet of the diverter 360 may be located at the top end of the diverter 360 instead of in the back wall of the diverter shown in FIG. 6C. The top end of the diverter 360 may include flanges 364 and an inlet at the bottom end of the exhaust duct 370 may include corresponding flanges 374. The gasket 376 may be disposed between the flanges 364, 374 to connect the diverter 360 and the exhaust duct 370. The gasket 376 may operate to increase assembly tolerances when lifting and/or assembling the lower and upper module sets 10a, 10b. For example, the exhaust ducts 370 may be pre-assembled with the upper module set 10b and the exhaust diverters 360 may be pre-assembled with the lower module set 10a. The upper module set 10b and upper skid 210b may be lifted over the lower module set 10a and the upper skid 210b may be seated onto the columns 240p, 240c. The gasket 376 may compensate for any positional deviation.

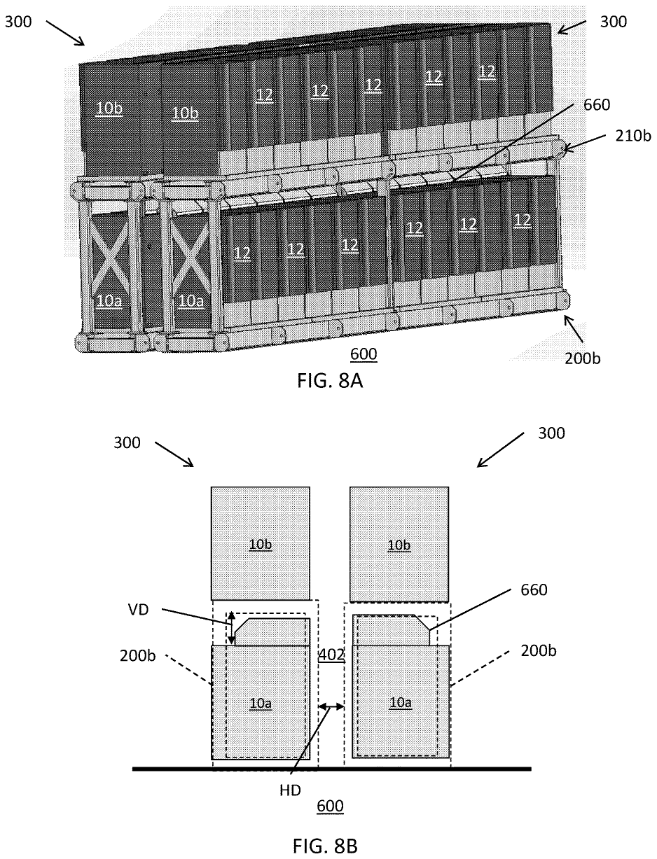

FIG. 8A is a perspective view of a system 600, according to various embodiments of the present disclosure, and FIG. 8B is cross-sectional view of the system 600 of FIG. 8A. The system 600 may be similar to the system 500. Accordingly, only the differences therebetween will be described in detail.

Referring to FIGS. 8A and 8B, the system 600 may include multiple generator stacks 300, which may be similar to the generator stacks described above. For example, the generator stacks 300 that may each include a lower module set 10a, an upper module set 10b, and a support frame 200b. While the support frame 200b is shown, the system 600 may include any of the other support frames described herein.

The generator stacks 300 may be configured such that the lower module sets 10a are positioned closer to the upper module sets 10b, as compared to the system 400 of FIG. 6A. In particular, a vertical separation distance VD between the modules of the lower module sets 10a and the upper skids 210b may range from about 15 inches to about 20 inches. In comparison, the system 400 may have a vertical separation distance ranging from about 30 inches to about 40 inches, in order to accommodate module servicing. The horizontal separation distance HD may also be reduced.

The module sets 10a, 10b may be modified to facilitate the reduction of the vertical separation distance VD and/or the horizontal separation HD. For example, the module sets 10a, 10b may include relatively short diverters 660 and/or power modules 12 designed to facilitate servicing from the front side of the module sets 10a, 10b.

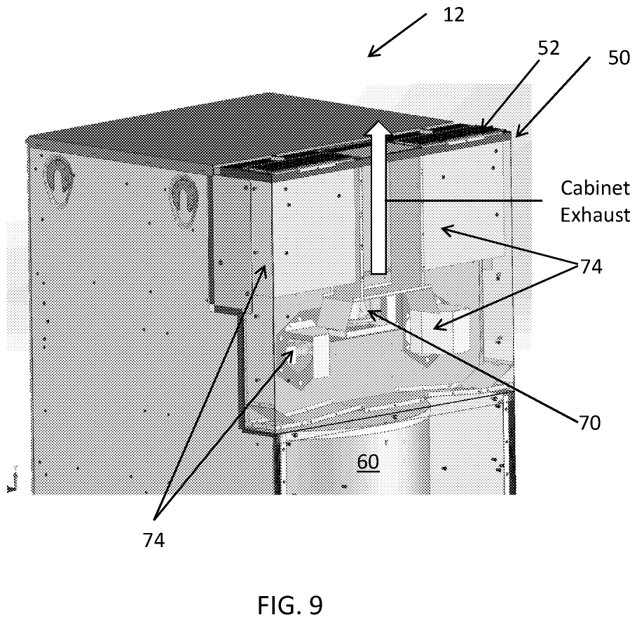

FIG. 9 is an external backside view of an exemplary power module 12. The power module 12 may be located in the system 600 of FIGS. 8A and 8B.

The power modules 12 may include a hotbox 60 and various balance of plant system components (e.g., blowers, valves, conduits, etc.) and an electronics cabinet where power electronics (e.g., DC/DC converters, not shown) may be disposed. The ventilation unit 50 may be disposed on the back sides of the power module 12 opposite to the door 20 (not shown, see FIG. 1). A cabinet fan 70 may be disposed in the hotbox cabinet and may be configured to force hotbox cabinet air into the ventilation unit 50. The cabinet fan 70 may be accessible from the front of the hotbox cabinet 62 to allow easy access thereto via the door 20. Cabinet exhaust may be directed upward through the ventilation unit 50 and out of the power module 12. High temperature hotbox exhaust may be output from the hotbox 60 through high temperature exhaust ducts 74 in the ventilation unit 50 and then exit the ventilation unit through the vents 52.

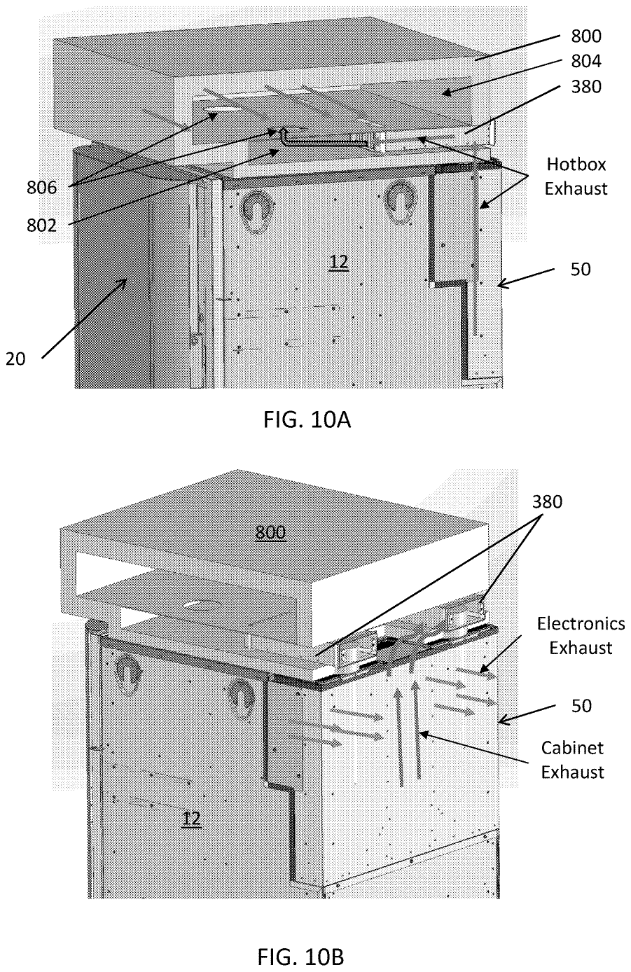

FIG. 10A is a perspective view showing a hotbox exhaust flow through a high temperature exhaust diverter 800 and an associated power module 12, according to various embodiments of the present disclosure, and FIG. 10B is a perspective view showing cabinet exhaust and electronics exhaust flow through the exhaust diverter 800 and power module 12 of FIG. 10A.

Referring to FIGS. 10A and 10B, the exhaust diverter 800 may be disposed on top of the power module 12 and may be fluidly connected to adjacent exhaust diverters 800 to form a high temperature exhaust manifold. The exhaust diverter 800 may be divided into a first chamber 802 and a second chamber 804, which may be fluidly connected by exhaust apertures 806. The second chamber 804 may overlie the first chamber 802. A filter module 380 that includes an exhaust filter, such as an electrostatic particulate exhaust filter, may be disposed in the first chamber 802.

High temperature hotbox exhaust may be output from the hotbox 60 to the ventilation unit 50. The hotbox exhaust may flow in the high temperature exhaust ducts 74 in the ventilation unit 50, and then from the ventilation unit 50 into the exhaust filter module 380 through the vents 52. The hotbox exhaust output from the filter module 380 may flow through the first chamber 802 in a first horizontal direction, before flowing upwards through the exhaust apertures 806 and entering the second chamber 804. The hotbox exhaust may flow through the second chamber 804 in a second horizontal direction perpendicular to the first horizontal direction. Exhaust from other power modules 12 may also flow through the second chamber 804. Adjacent second chambers 804 form the high temperature exhaust manifold.

Cabinet exhaust and electronics exhaust may be exhausted from the ventilation unit 50 without entering the exhaust manifold 800. The cabinet exhaust and electronics exhaust may be routed around the sides of the high temperature exhaust ducts 74 in the ventilation unit 50. Accordingly, the exhaust manifold 800 may be configured to collect hot hotbox exhaust from multiple power modules 12 and provide the hot hotbox exhaust for thermal recovery (e.g., to form a combined power and heat (CHP) system). For example, the hotbox exhaust may be provided to a heat exchanger to generate hot water or hot air. Alternatively, the hotbox exhaust may be provided to an absorption chiller for cooling applications.

In various embodiments, the power modules 12 may comprise either fuel cell power generation modules or electrolyzer cell hydrogen generation modules. In the fuel cell power generation modules, fuel and air are provided to fuel cell stacks or columns, and air and fuel exhaust streams are provided from the fuel cell stacks or columns to an anode tail gas oxidizer (ATO) located in the hotbox 60. The fuel exhaust stream is oxidized by the air exhaust stream in the ATO to generate the hot hotbox exhaust stream which flows from the ATO to the high temperature exhaust ducts 74 in the ventilation unit 50. In hydrogen generation modules, electric power is applied to electrolyzer cell stacks or columns to electrolyze steam into a hydrogen product stream and an oxygen enriched air hot hotbox exhaust stream.

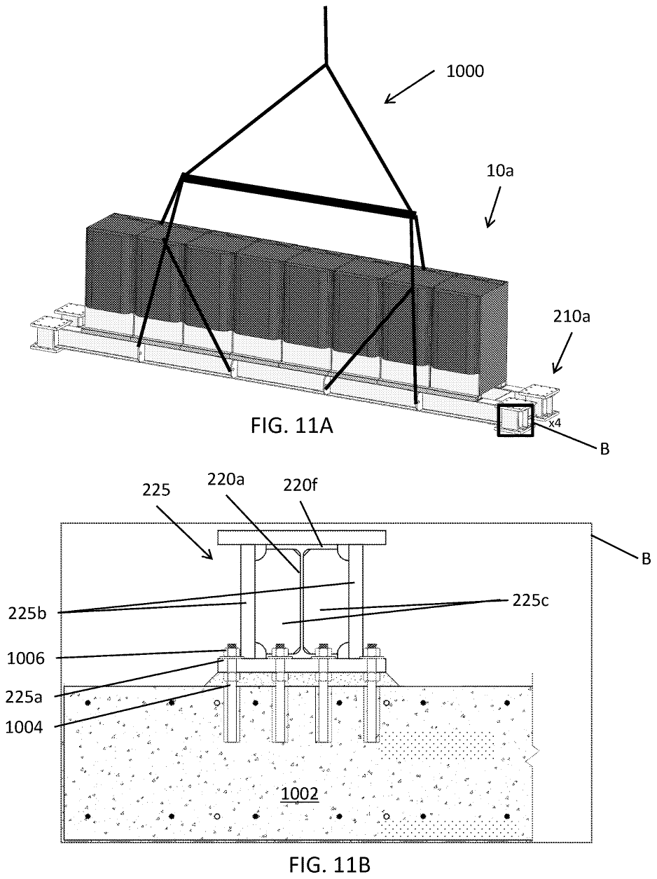

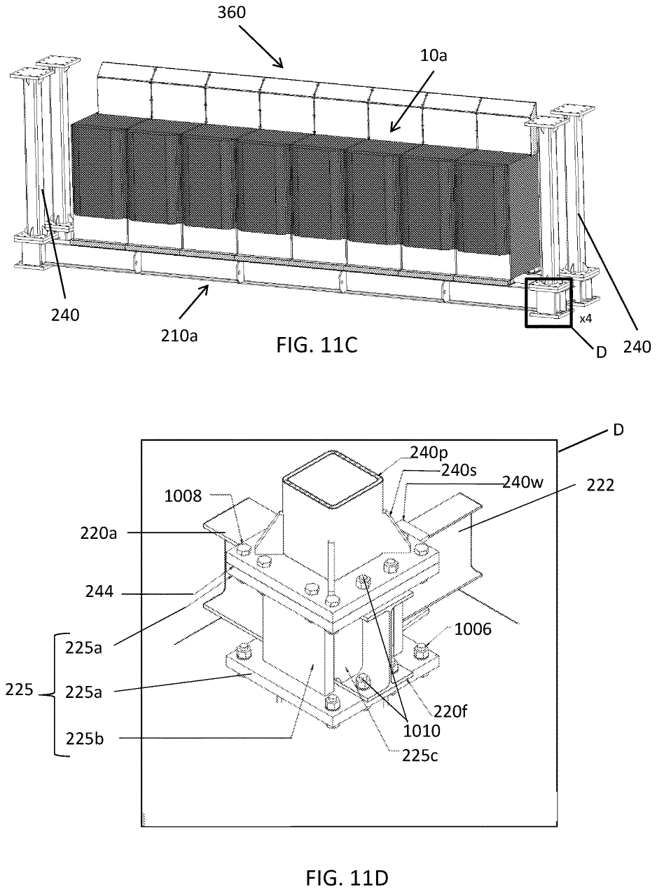

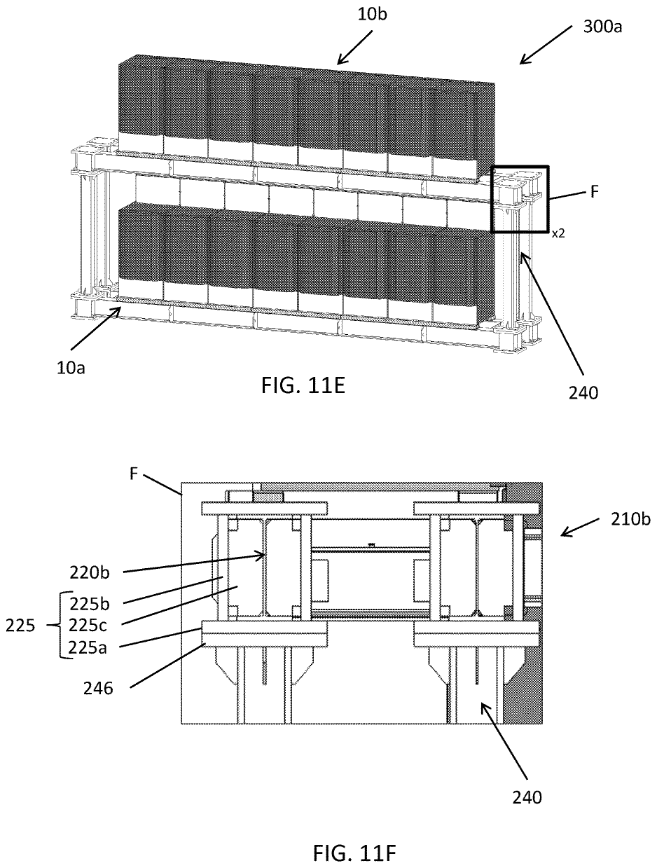

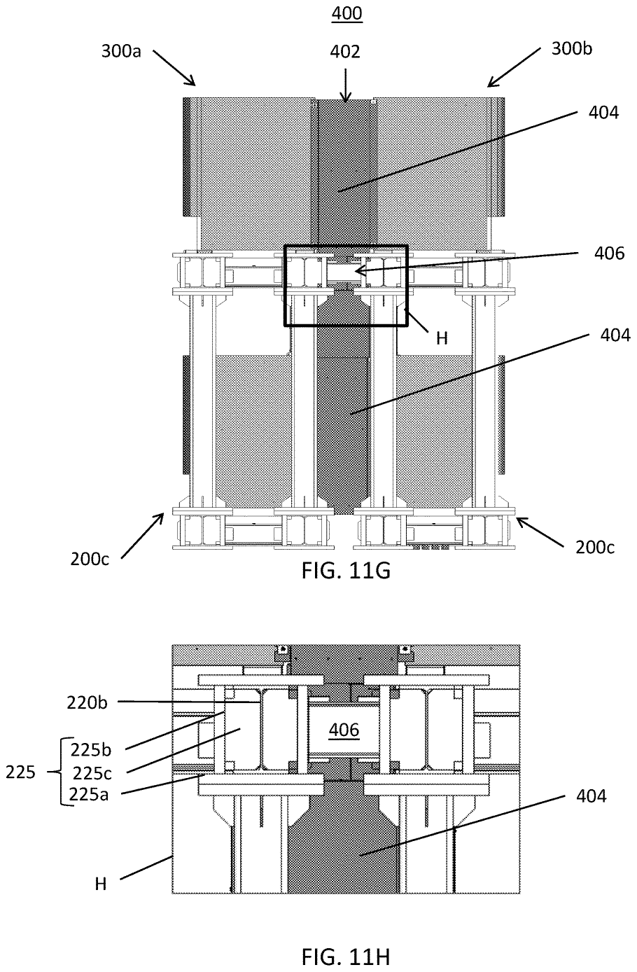

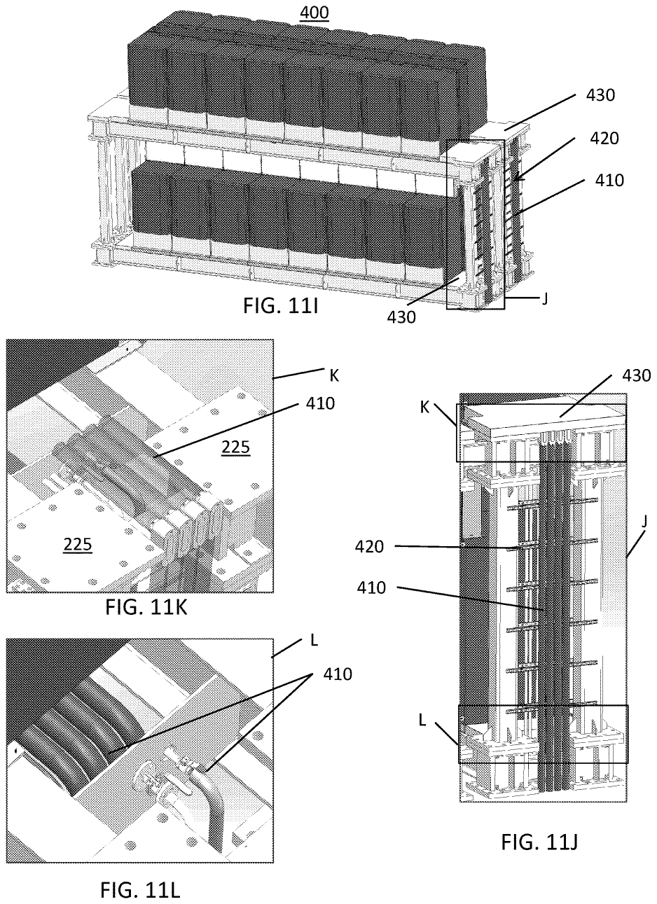

FIGS. 11A-11L illustrate a method of assembling a system 400, according to various embodiments of the present disclosure. While the method is described with respect to system 400, the method is also applicable to assembling any of the systems disclosed herein.

Referring to FIGS. 11A and 11B, a lower module set 10a may be attached to rigging 1000 and lifted into position at a site. For example, the lower module set 10a may be lifted from a truck by a crane and positioned onto a concrete pad 1002 and anchored in place. For example, the lower skid beams 220a may be anchored to the pad 1002 using bolts 1004 that extend through the lower skid beams 220a and/or horizontal plates 225a of the corner supports 225. The bolts 1004 may be fixed to the horizontal plates 225a by nuts 1006 located above the horizontal plates 225a. Optional end stiffener plates 225c may be vertically positioned perpendicular to the vertical plates 225b and inserted in between the flanges 220f of the lower skid beams 220a.

Referring to FIGS. 11C and 11D, columns 240 may be attached to the lower skid beams 220a. In particular, the lower brackets 244 of the columns 240 may be bolted to the lower skid beams 220a. For example, the lower brackets 244 may be bolted to the horizontal plates 225a of the corner supports 225 of the lower skid beams 220a using bolts 1008. The flanges 220f may be bolted to the horizontal plates 225a by bolts 1010. As shown FIG. 11C, four columns 240 may be bolted to opposing ends of the lower skid beams 210. However, additional columns, such as central columns, may also be included in some embodiments. Diverters 360 may be attached to the top of the modules of the lower module set 10a. The diverters 360 may be configured to laterally divert exhaust from the lower module set 10a into the aisle 402. The columns 240 may optionally include diagonally extending column stiffeners 240s. An optional weld joint 240w may be provided between the columns 240 and the cross braces 222.

Referring to FIGS. 11E and 11F, the upper skid beams 220b may be placed on the support beams 240. For example, the horizontal plates 225a of the corner supports 225 of the upper skid beams 220b may be bolted to the upper brackets 246 of the columns 240. The upper module set 10b is then placed on the upper skid beams 220b over the lower module set 10a. For example, the upper module set 10b may be lifted into position using rigging and a crane as shown in FIG. 11A. The upper module set 10b may then be attached to the upper skid beams to form the first generator stack 300a.

Referring to FIGS. 11G and 11H, the second generator stack 300b may be assembled adjacent to the first generator stack 300a using the steps described above to form the system 400. In particular, the generator stacks 300a, 300b may be positioned back to back to form the aisle 402.

The support frames 200c of the generator stacks 300a, 300b may be connected using tie blocks 406. For example, the tie blocks 406 may connect adjacent corner supports 225 of the support frames 200c. In some embodiments, the tie blocks 406 may be bolted to the vertical plates 225a of the corner supports 225 to structurally connect the support frames 200c. In various embodiments, side panels 404 may be attached to the system 400 to cover the sides of the aisle 402.

Referring to FIGS. 11I-11L, utility connections 410, such as wiring and fluid conduits (e.g., fuel and water conduits), may be connected to system 400 to provide fluids such as water, fuel, and/or steam to the system 400 and to electrically connect the system 400 to external loads and/or power sources, for fuel cell and electrolyzer cell systems, respectively. In some embodiments, the system 400 may optionally include strut supports 420 to support the utility connections 410. In some embodiments, the system 400 may optionally include cover plates 430 disposed on the corner supports 225 to protect the utility connections 410.

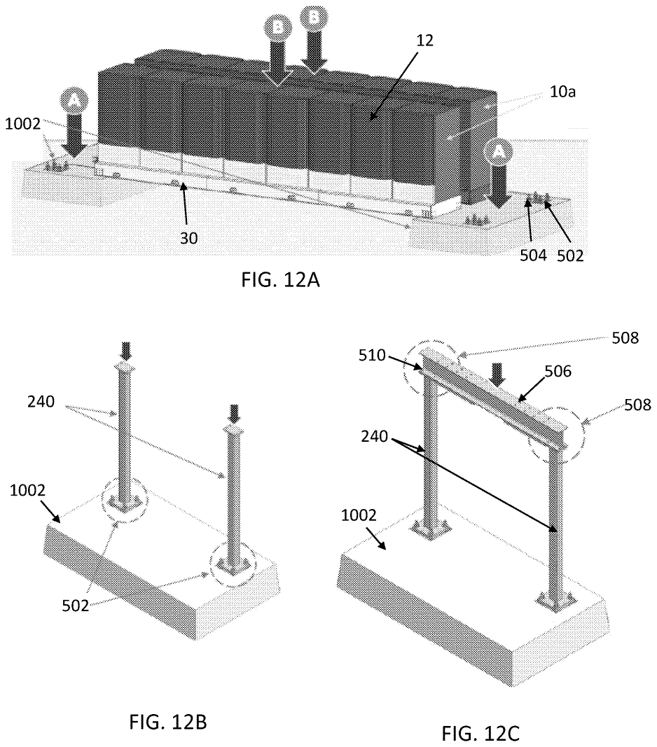

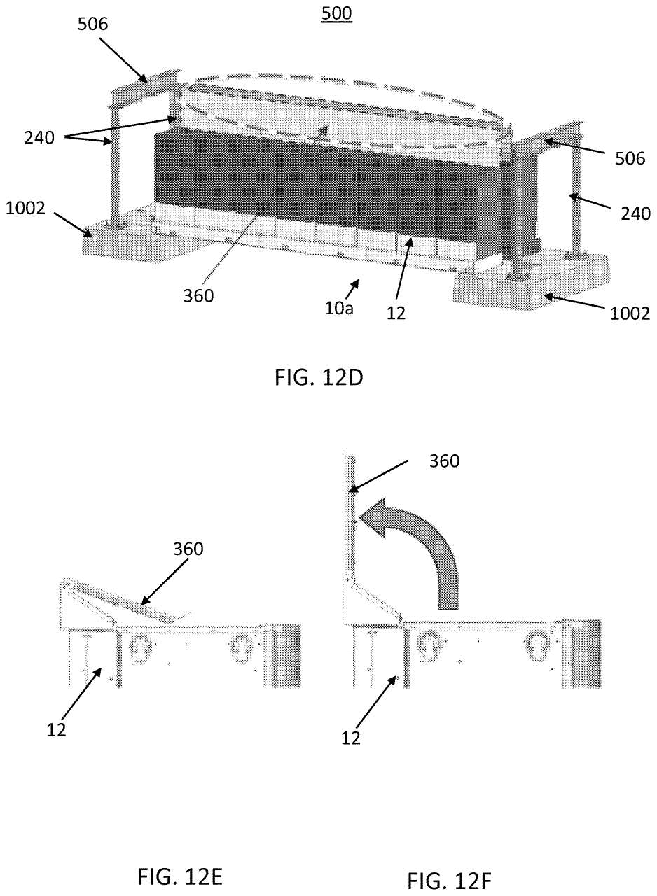

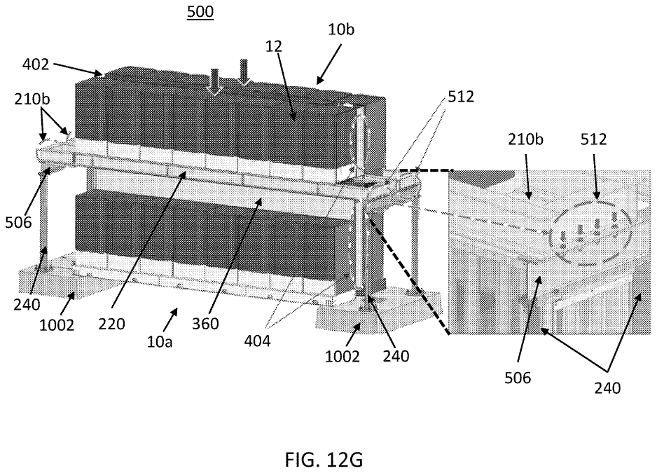

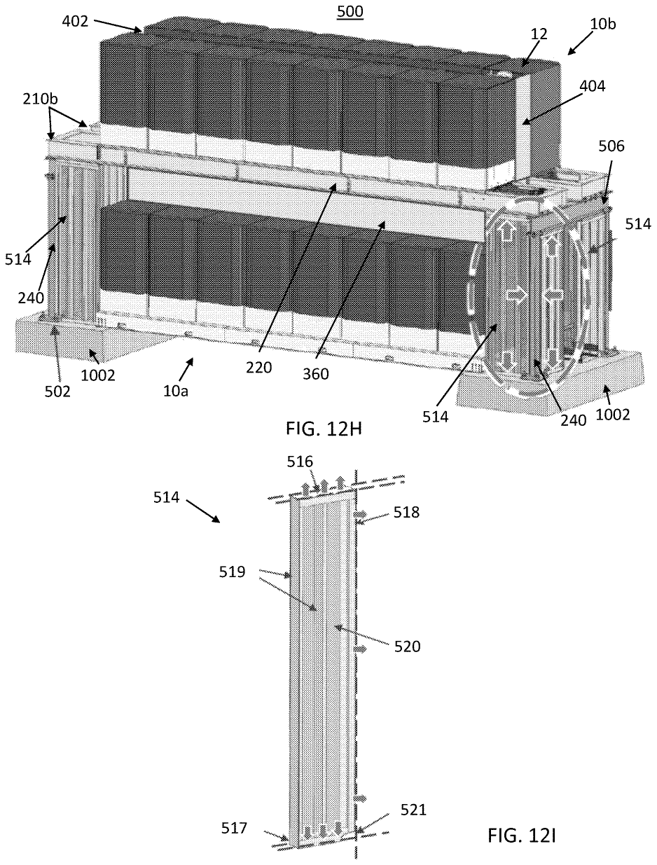

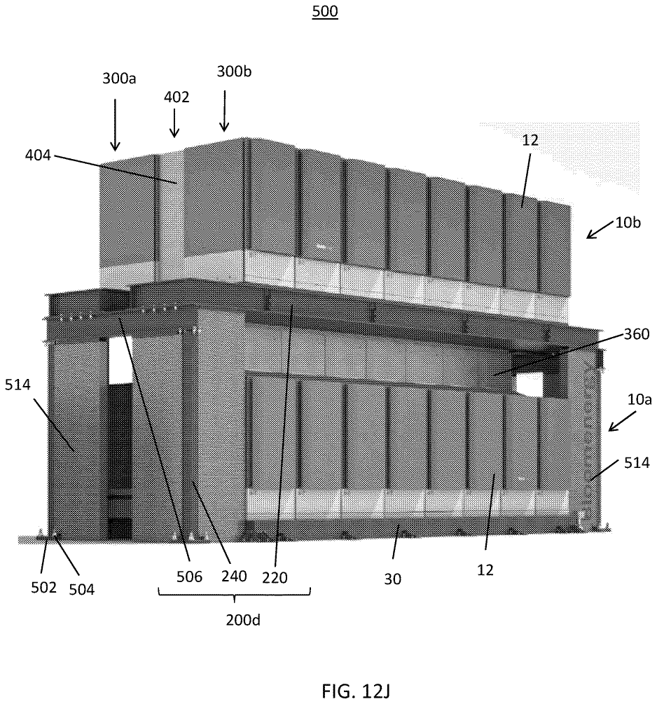

FIGS. 12A-12J illustrate steps in a method of assembling a system 500 according to another embodiment. Referring to FIG. 12A, in a first step “A”, trenches are dug out in the ground, and two pads 1002 with precast footings 502 are disposed in the respective trenches. The pads 1002 may comprise concrete pads, such as pre-cast concrete pads. The footings 502 may comprise metal plates with openings. Each pad 1002 may include plural footings 502, such as two footings 502. Bolts 504 extend through the openings in the footings 502 into the respective pad 1002. The bottom portions of the footings 502 and the bolts 504 may be embedded in the pads 1002. The trenches are backfilled with dirt or another fill material after step A is completed.

In a subsequent step “B”, the lower module set 10a is placed at ground level between the pads 1002, using a crane or other suitable machinery. The lower module set 10a may include power modules 12 disposed on a skid 30. The skid 30 may be placed directly onto the ground or onto a pad located on the ground. In one embodiment, opposing ends of the skid 30 may be disposed on the ends of the respective pads 1002.

Referring to FIG. 12B, the columns 240 are attached to the footings 502. Specifically, the columns 240 may be placed on the footings 502 such that the top portions of the bolts 504 extend through openings in the bottom of the columns 240. The bolts 504 are then secured to the columns 240 using nuts.

Referring to FIG. 12C, a cross-beam 506 is attached to the top ends 508 of each pair of columns 240 disposed on the respective pad 1002. The cross-beam 506 may be attached to the top ends 508 of the columns 240 using bolts 510 and nuts. The cross-beam 506 may comprise a metal (e.g., steel) I-beam in one embodiment. The cross-beam 506 may be used instead of the tie block 406 described in the previous embodiment.

Referring to FIGS. 12D-12F, the exhaust diverter 360 is extended over the lower module set 10a. In one embodiment shown in FIG. 12E, the exhaust diverter 360 portions may be attached to the top of the power modules 12 and folded down at the manufacturing site for transport to the installation site. Subsequently, after the lower module set 10a is installed at the installation site, the exhaust diverter 360 portions may be unfolded upwards, as shown by the arrow in FIG. 12F.

Referring to FIG. 12G, the upper skids 210b are attached to the cross-beams 506. Specifically, the skid beams 220 of the upper skid 210b may be bolted to the cross-beams 506 using bolts 512 and nuts, as shown in the inset in FIG. 12G. Subsequently, the upper module set 10b is placed on the upper skids 210b using a crane or other suitable machinery. Optional side panels 404 may be attached to opposing ends of the aisle 402 between the power modules 12 in the module set(s) 10a and/or 10b.

Referring to FIGS. 12H and 12I, shear walls 514 may be attached to the footings 502, the columns 240 and to the cross-beams 506. The shear walls 514 comprise rigid vertical structural walls that are designed to resist lateral forces, such as earthquakes and wind, and that act as stiff diaphragms, transferring horizontal loads down to the foundation (e.g. to the pads 1002 or ground), and preventing the system 500 from racking deformation, twisting, or collapsing. The shear walls 514 may be formed from metal (e.g., steel) or reinforced concrete.

As shown in FIG. 12I, in one embodiment, each shear wall 514 may comprise an upper track 516, a lower track 517, side track 518, stud beams (e.g., vertical C-stud beams) 519, and sheet metal (e.g., cold formed steel sheet) cladding 520 attached to the tracks and the stud beams. The tracks may be attached to the footings 502, the columns 240 and to the cross-beams 506 using any suitable attachment method, such as self-tapping screws, as shown by the arrows in FIG. 12I. The lower track 517 may include a notch 521 for the footing.

FIG. 12J illustrates the completed system 500. The skid beams 220, the columns 240, and the cross-beams 506 form the support frame 200d. The support frame 200d is a gravity frame that is attached to the shear walls 514 that function as lateral support elements. Alternatively, a buckling restrained brace (BRB) may be used as a lateral support element instead of or in addition to the shear walls 514.

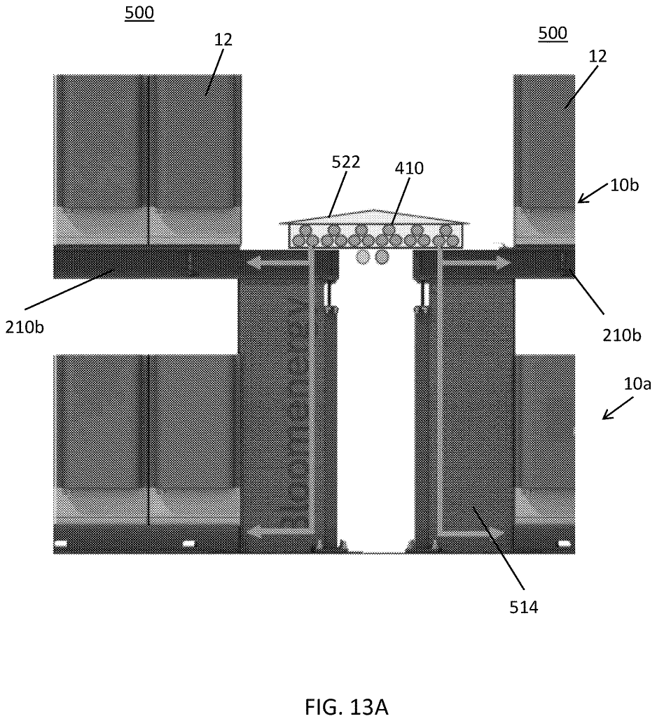

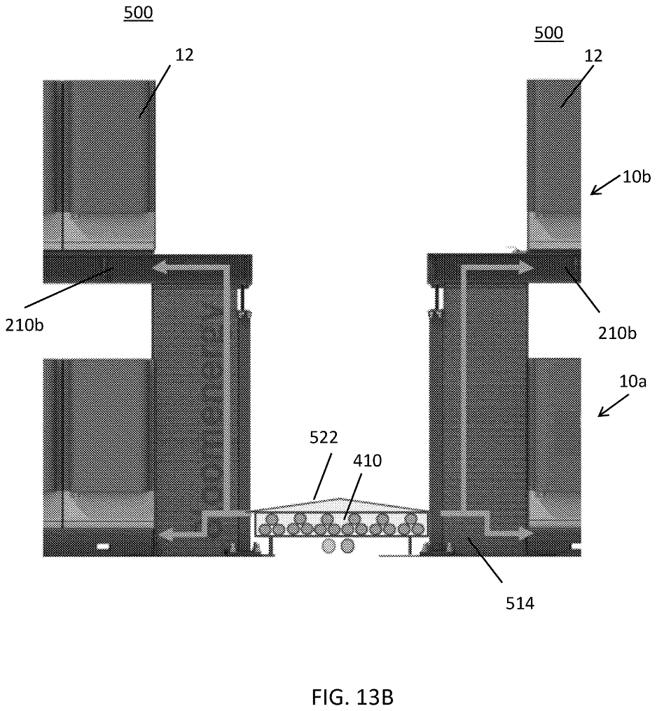

Referring to FIGS. 13A and 13B, the utility connections 410 may be connected to the system 500 either at the level the upper skid 210b and/or at ground level, respectively. The utility connections 410 may be provided in one or more trays or feedthroughs 522, and may be connected to plural systems 500.

The arrangements of the fuel cell systems, as shown in the various exemplary embodiments, are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein.

Some elements shown as integrally formed may be constructed of multiple parts or elements, the position of elements may be reversed or otherwise varied, and the nature or number of discrete elements or positions may be altered or varied. Other substitutions, modifications, changes and omissions may also be made in the design, operating conditions and arrangement of the various exemplary embodiments without departing from the scope of the present disclosure. Any one or more features of any embodiment may be used in any combination with any one or more other features of one or more other embodiments.

1. A generator stack, comprising:
a lower skid;
a row of lower power modules disposed on the lower skid;
support columns extending vertically from the lower skid;
an upper skid disposed on the support columns over the row of lower power modules; and
a row of upper power modules disposed on the upper skid, wherein the lower power modules and the upper power modules each comprise a hotbox and at least one stack of electrochemical cells disposed in the hotbox.

2. The generator stack of claim 1, wherein:
the lower skid comprises lower skid beams and lower pedestal assemblies disposed on the lower skid beams, and comprising lower pedestals;
the row of the lower power modules is disposed on the lower pedestals;
the support columns extend vertically from the lower skid beams;
the upper skid comprises upper skid beams disposed on the support columns and upper pedestal assemblies disposed on the upper skid beams, and comprising upper pedestals; and
the row of upper power modules is disposed on the upper pedestals.

3. The generator stack of claim 2, wherein the support columns comprise:
peripheral columns that connect opposing ends of the upper skid beams to opposing ends of the lower skid beams; and
central columns disposed between the peripheral support columns and that connect central portions of the lower skid beams to central portions of the upper skid beams.

4. The generator stack of claim 3, wherein the central columns extend vertically between the lower power modules.

5. The generator stack of claim 2, further comprising:
cross braces that connects the upper skid beams to each other, and that connects the lower skid beams to each other;
latitudinal bracing that connects adjacent pairs of support columns to each other; and
longitudinal bracing that connects at least one support column of each pair of support columns to a respective one of the lower skid beams.

6. The generator stack of claim 5, wherein:
the upper and lower skid beams comprise metal I-beams; and
the generator stack comprises attachment plates that are inserted into the I-beams and welded to the I-beams and the longitudinal bracing.

7. The generator stack of claim 1, further comprising:
exhaust diverters disposed on top of the lower power modules and configured to receive exhaust from the hotboxes of the lower power modules;
exhaust ducts disposed on a backside of the upper power modules and configured to receive the exhaust from the exhaust diverters and output the exhaust at the top of the generator stack; and
vents disposed on top of the upper power modules and configured to receive exhaust from the hotboxes of the upper power modules.

8. The generator stack of claim 7, further comprising exhaust filter modules that are disposed in the exhaust ducts and that are accessible from the top of the generator stack.

9. The generator stack of claim 7, further comprising plenums located in the exhaust ducts and that divide the exhaust ducts into first compartments that are configured to receive the exhaust from the hotboxes of the lower power modules and second compartments configured to receive cabinet exhaust which is cooler than the exhaust from the hotboxes.

10. The generator stack of claim 7, further comprising gaskets disposed between the exhaust ducts and the exhaust diverters.

11. A system, comprising:
a first generator stack of claim 7;
a second generator stack; and
an aisle located between the first generator stack and a second generator stack, wherein the exhaust diverters and the exhaust ducts are located in the aisle.

12. The generator stack of claim 2, wherein:
the support columns comprise peripheral columns that connect opposing ends of the upper skid beams to opposing ends of the lower skid beams;
corner braces that extend from the peripheral support columns to the upper skid beams; and
an angle formed between each peripheral column and the corresponding corner brace ranges from about 20° to about 40°.

13. The generator stack of claim 12, wherein:
the upper and lower skid beams comprise metal I-beams;
attachments plates are inserted into the I-beams and welded to the I-beams and the longitudinal bracing; and
the attachment plates comprise peripheral attachment plates that vertically overlap with corresponding ones of the peripheral columns.

14. The generator stack of claim 2, wherein:
the upper and lower pedestal assemblies each comprise:
a base that is attached to a corresponding upper or lower skid beam;
a wall that extends vertically from the base; and
a plurality of the pedestals disposed on the base; and
each of the power modules is disposed on a portion of the plurality of the pedestals between two of the walls.

15. The generator stack of claim 1, further comprising exhaust diverters disposed on each of the lower power modules, the exhaust diverters each comprising:
a lower chamber configured to receive hotbox exhaust from the respective hotbox;
an exhaust module disposed in the lower chamber and comprising an exhaust filter;
an upper chamber disposed on the lower chamber; and
exhaust apertures fluidly connecting the upper chamber to the lower chamber, and configured to provide the hotbox exhaust from the lower chamber to the upper chamber.

16. The generator stack of claim 15, wherein the upper chambers of the exhaust diverters of the lower power modules are fluidly connected to one another to form an exhaust manifold that receives the hotbox exhaust from all of the lower power modules.

17. The generator stack of claim 15, wherein the lower power modules comprise ventilation units that are configured to provide the hotbox exhaust to the lower chambers and to output hotbox cabinet exhaust and electronics cabinet exhaust from the lower power modules.

18. The generator stack of claim 1, wherein the at least one stack of electrochemical cells comprises at least one stack of fuel cells or electrolyzer cells.

19. The generator stack of claim 1, further comprising:
utility connections disposed in at least one tray or feedthrough, and connected to the lower and upper power modules;
at least one lateral support element attached to the support columns; and
cross-beams attached to top ends of the support columns, wherein the upper skid is attached to the cross-beams.

20. The generator stack of claim 1, wherein:
the at least one tray or feedthrough is disposed at ground level or at a level of the upper skid;
the lower skid is disposed at least in part on the ground;
the support columns are bolted to metal footers embedded in concrete pads located at opposite ends of the lower skid;
the upper skid, the support columns, and the cross-beams form a gravity support frame that is attached to the at least one lateral support element; and
the at least one lateral support element comprises at least one of a plurality of shear walls or a buckling restrained brace.

21. A method of assembling the generator stack of claim 20, comprising:
placing the concrete pads containing the embedded metal footers into trenches in the ground;
placing the row of the lower power modules disposed on the lower skid at least partially on the ground between the concrete pads;
bolting the support columns to the metal footers;
bolting the cross-beams to the top ends of the support columns;
unfolding an exhaust diverter that is connected to the lower power modules;
bolting the upper skid to the cross-beams;
placing the row of the upper power modules on the upper skid; and
attaching the shear walls to the metal footers, the support columns, and the cross-beams.

22. A method of operating the generator stack of claim 1, comprising:
providing exhaust from the hotboxes of the lower power modules into exhaust diverters disposed on top of the lower power modules;
providing the exhaust from the exhaust diverters to exhaust ducts disposed on a backside of the upper power modules;
outputting the exhaust from the exhaust ducts at a top of the generator stack; and
providing exhaust from the hotboxes of the upper power modules through vents disposed on top of the upper power modules.
